(19) United States
(12) Patent Application Publication
(10) Pub. No.: US 2011/0058252 A1
(43) Pub. Date: Mar. 10, 2011

(54) BOTTOMLESS MICRO-MIRROR WELL FOR 3D IMAGING FOR AN OBJECT OF INTEREST

(75) Inventors: Chris Janetopoulos, Nashville, TN (US); Dmitry Markov, Nashville, TN (US); Ronald S. Reiserer, Nashville, TN (US); Kevin T. Seale, Nashville, TN (US); John P. Wikswo, Brentwood, TN (US); Charles Wright, Chicago, IL (US)

(73) Assignee: VANDERBILT UNIVERSITY, Nashville, TN (US)

(21) Appl. No.: 12/788,186

(22) Filed: May 26, 2010

Related U.S. Application Data
(63) Continuation-in-part of application No. 11/943,222, filed on Nov. 20, 2007.
(60) Provisional application No. 60/860,755, filed on Nov. 22, 2006.

(51) Int. Cl. G02B 21/04; G02B 5/09; G03F 7/20; G06K 9/00

(52) U.S. Cl. 359/368; 359/851; 430/322; 382/154

(57) ABSTRACT

A bottomless micro-mirror well. In one embodiment, the bottomless micro-mirror well includes a substrate having a first surface and an opposite, second surface defining a body portion between the first surface and the opposite, second surface, where the body portion defines an inverted pyramidal well having at least three side surfaces extending to each other and defining an opening between a first sidewall and a second sidewall of the body portion, and where each of the at least three side surfaces is configured to reflect light emitting from an object of interest.

### CROSS-REFERENCE TO RELATED PATENT APPLICATION

This application is a continuation-in-part of U.S. patent application Ser. No. 11/943,222, filed Nov. 20, 2007, entitled “PHOTOLITHOGRAPHED MICRO-MIRROR WELL FOR 3D TOMOGRAM IMAGING OF INDIVIDUAL CELLS,” by Kevin Truett Seale, Ron Reiserer, and John Wikswo, which is incorporated herein by reference in its entirety and which itself claims the benefit, pursuant to 35 U.S.C. §119(e), of U.S. provisional patent application Ser. No. 60/860,755, filed Nov. 22, 2006, entitled “PHOTOLITHOGRAPHED MICRO-MIRROR WELL FOR 3D TOMOGRAM IMAGING OF INDIVIDUAL CELLS,” by Kevin Truett Seale, Ron Reiserer and John Wikswo, which is incorporated herein by reference in its entirety.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference.

### STATEMENT OF FEDERALLY-SPONSORED RESEARCH

The present invention was made with Government support awarded by the Air Force Office of Scientific Research (AFOSR) under Contract No. FA9550-05-1-0349. The United States Government has certain rights to this invention pursuant to this grant.

### FIELD OF THE INVENTION

The present invention relates generally to a bottomless micro-mirrored well, and more particularly to a bottomless micro-mirrored pyramidal well, its applications in multi-perspective three-dimensional (3D) microscopy to simultaneously collect images of an object of interest from multiple vantage points and a method of manufacturing same.

### BACKGROUND OF THE INVENTION

One of the burgeoning areas of the development of modern microscopy is three-dimensional (3D) microscopy, which acquires a three-dimensional image with every image plane sharply in focus. This is in contrast to conventional microscopy where the image of the in-focus plane is superposed with a blurred image of out-of-focus planes. Several developments of 3D microscopy have been reported. These techniques have been gaining popularity in the scientific and industrial communities. Typical applications include life sciences and semiconductor inspection.

An inverted microscope is a microscope with its light source and condenser on the top above the stage pointing down, and the objectives and turret are below the stage pointing up. Inverted microscopes are useful for observing living cells or organisms at the bottom of a container of fluid (e.g., a well-plate with a thin bottom, or a tissue culture flask) under more natural conditions than on a glass slide, with an objective some distance above the sample, as is the case with a conventional microscope. Some inverted microscopes are also capable of epi-illumination, in which light is passed through the microscope objective lens to illuminate the sample from the same side that it is observed. This is particularly useful for fluorescence imaging, wherein the excitation and emission light are at different wavelengths and can be separated with optical filters.

In confocal scanning microscopy (CSM), the out-of-focus signal is spatially filtered out by confocal aperturing of the object illumination and the detector points. The 3D image is constructed by pixel-by-pixel mechanical scanning of the entire object volume, which places a fundamental limit on the image acquisition speed.

A catadioptric system that uses a curved mirror to map a panoramic view onto a single sensor is able to obtain multi-perspective 3D images of an object, but has limited sensor resolution. Furthermore, the resolution varies significantly with the viewing direction across the field of view (FOV).

Therefore, a heretofore unaddressed need exists in the art to address the aforementioned deficiencies and inadequacies.

### SUMMARY OF THE INVENTION

In one aspect, the present invention relates to a bottomless micro-mirror well. In one embodiment, the bottomless micro-mirror well includes a substrate having a first surface and an opposite, second surface and defining a body portion between the first surface and the second surface, where the body portion defines an inverted pyramidal well having at least three side surfaces extending to each other and defining an opening between a first sidewall and a second sidewall, and where each of the at least three side surfaces is configured to reflect light emitting from an object of interest. The horizontal cross-sectional shape of the inverted pyramidal well is a polygon or a circle. The vertical cross-sectional shape of the inverted pyramidal well is a trapezoid if the well has an even number of sides or is circular, and an irregular quadralateral if the well has an odd number of sides. The object of interest is a biological analyte that includes cells and proteins. Also, each of the side surfaces includes a dichroic mirror.

In another embodiment, the bottomless micro-mirror well enables transillumination of an object within or adjacent to the well, such that light scattered or emitted fluorescently from the object is collected by the mirrors on the sides of the well.

In one embodiment, the bottomless micro-mirror well enables epi-illumination of the object through the microscope objective but does not produce a direct reflection of this illumination light back into the objective because the well does not have a mirrored bottom as would occur in the wells described in the earlier patent application.

In one embodiment, the bottomless micro-mirror well enables the use of a post or platform passing through the smaller opening of the well to allow mechanical positioning of the object within the well, for example to adjust the position of the object within the well to the point where the images are at a chosen depth of focus for the objective.

In another embodiment, the bottomless micro-mirror well allows the flow of fluids through the opening of the well to deliver drugs or toxins to affect the object being observed or provide nutrients and remove metabolic products of a living cell or organism being maintained within the well.

In one embodiment, the substrate includes a silicon wafer, and the object of interest includes a biological analyte with cells and proteins. Each of the at least three side surfaces defines an angle θ₁ relative to the second surface, where the angle θ₁ is in the range of 0°<θ₁<90°. For a point object, the inverted pyramidal well produces images that are equidistant from all of the side surfaces, and the position where the object should be located to accomplish this is termed the focus of the well, is inside the inverted pyramidal well and equidistant from all side surfaces. In operation, the inverted pyramidal well is positioned in relation to the object of interest such that the object of interest is located inside of the inverted pyramidal well.

In another embodiment, the position of the focus is outside the inverted pyramidal well. In this embodiment, in operation, the inverted pyramidal well is positioned in relation to the object of interest such that the object of interest is located outside of the inverted pyramidal well.

In another aspect, the present invention relates to a process of fabricating a bottomless micro-mirror well. In one embodiment, the process includes the steps of providing a silicon substrate and etching off the silicon substrate to form a bottomless inverted pyramidal well in the silicon substrate, where the bottomless inverted pyramidal well has a first end, an opposite, second end, and a plurality of side surfaces extending to each other and defining an opening at the second end. The process also includes the step of performing photolithographically masking and evaporating processes on the plurality of side surfaces, to form a mirrored pyramidal well. The bottomless inverted pyramidal well has a central axis running through the center of the well, from a first end to a second end, as well as a planar axis that is perpendicular to the central axis, where each of the plurality of side surfaces is formed to define an angle θ₁ relative to the planar axis. The etching step is performed with a potassium hydroxide (KOH) etching process.

In one embodiment, the process further includes the step of fabricating a master mold from the mirrored pyramidal well, for replication of at least one additional mirrored pyramidal well. The master mold is fabricated through hot embossing, injection molding, casting, and/or another method of mass fabrication of objects.

In yet another aspect, the present invention relates to a three-dimensional microscope. In one embodiment, the three-dimensional microscope includes a microscope objective lens adapted for focusing light from a plurality of mirrors configured to simultaneously collect images of an object of interest from multiple vantage points. The object of interest includes a biological analyte including cells and proteins. The plurality of mirrors forms one or more bottomless mirrored pyramidal wells, where each of the plurality of mirrors has an angle θ₁ relative to a horizontal axis that is orthogonal to a vertical axis. The angle θ₁ is in the range of 0<θ₁<90°.

In one embodiment, the three-dimensional microscope also includes a microfluidic structure in communication with the one or more bottomless mirrored pyramidal wells. The one or more bottomless pyramidal wells is/are made from the smooth angled surfaces of anisotropically etched silicon. Each of the plurality of mirrors includes a dichroic mirror capable of reflecting specific wavelength ranges into a collection cone of the microscope objective lens. The plurality of mirrors is affixed such that the perimeter of the field of view of the microscope objective lens contains reflected images of the object of interest.

In one embodiment, the plurality of mirrors is affixed opposite the object of interest from the microscope objective lens, for collecting reflected images of the object of interest.

In yet another aspect, the present invention relates to a three-dimensional microscope. In one embodiment, the three-dimensional microscope includes a microscope objective that is adapted for focusing the light produced by a plurality of mirrors that are configured to simultaneously collect images of an object of interest, from multiple vantage points. Each of the plurality of mirrors forms one or more bottomless mirrored pyramidal wells. At least one of the bottomless pyramidal wells that are formed is made from the smooth angled surfaces of anisotropically etched silicon. The object of interest includes a biological analyte with cells and proteins, and a microfluidic structure that is in communication with the bottomless mirrored pyramidal well.

In one embodiment, each of the plurality of mirrors defines an angle θ₁ relative to a horizontal axis that is orthogonal to a vertical axis, where the angle θ₁ is in the range of 0<θ₁<90°. Each of the plurality of mirrors comprises a dichroic mirror that is capable of reflecting specific wavelength ranges into a collection cone of the microscope objective lens. Also, the plurality of mirrors is affixed such that the perimeter of the field of view of the microscope objective lens contains reflected images of the object of interest.

In another embodiment, the plurality of mirrors is affixed opposite an object of interest from the microscope objective lens, for collecting reflected images of the object of interest.

In yet another aspect, the present invention relates to a method for reconstruction of simultaneous, multi-vantage point images into three-dimensional structures of an object of interest. In one embodiment, the method includes the steps of simultaneously collecting images of the object of interest from multiple vantage points surrounding the object of interest, and mapping the collected images of the object of interest to form a three-dimensional image displaying the three-dimensional structures of the object of interest. The step of simultaneously collecting images of the object of interest is performed with a bottomless mirrored pyramidal well that has a plurality of side mirrored surfaces extending to each other and that define a first opening and a second opening. Each of the plurality of side mirrored surfaces has a first end and a second end such that the first opening is formed by the respective first ends of the side mirrored surfaces and the second opening is formed by the respective second ends of the side mirrored surfaces. Each of the plurality of side mirrored surfaces has an angle θ₁ relative to a horizontal axis that is orthogonal to a vertical axis, where the angle θ₁ is in a range of 0<θ₁<90°. The diameter of the first opening is greater than the diameter of the second opening.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 shows schematically a bottomless micro-mirror well according to one embodiment of the present invention: (A) a top view, and (B) a vertical cross-sectional view;

FIG. 2 shows an upright three-dimensional microscope with a bottomless inverted pyramidal well having introverted wells for collecting images of an object of interest within the well, according to one embodiment of the present invention;

FIG. 3 shows an upright three-dimensional microscope with a bottomless inverted pyramidal well having extroverted wells for collecting images of an object of interest outside the well, according to one embodiment of the present invention;

FIG. 4 shows an inverted three-dimensional microscope with a bottomless pyramidal well having introverted wells for collecting images of an object of interest within the well, according to one embodiment of the present invention; and

FIG. 5 shows an inverted three-dimensional microscope with a bottomless pyramidal well having extroverted wells for collecting images of an object of interest, according to one embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like parts throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise.

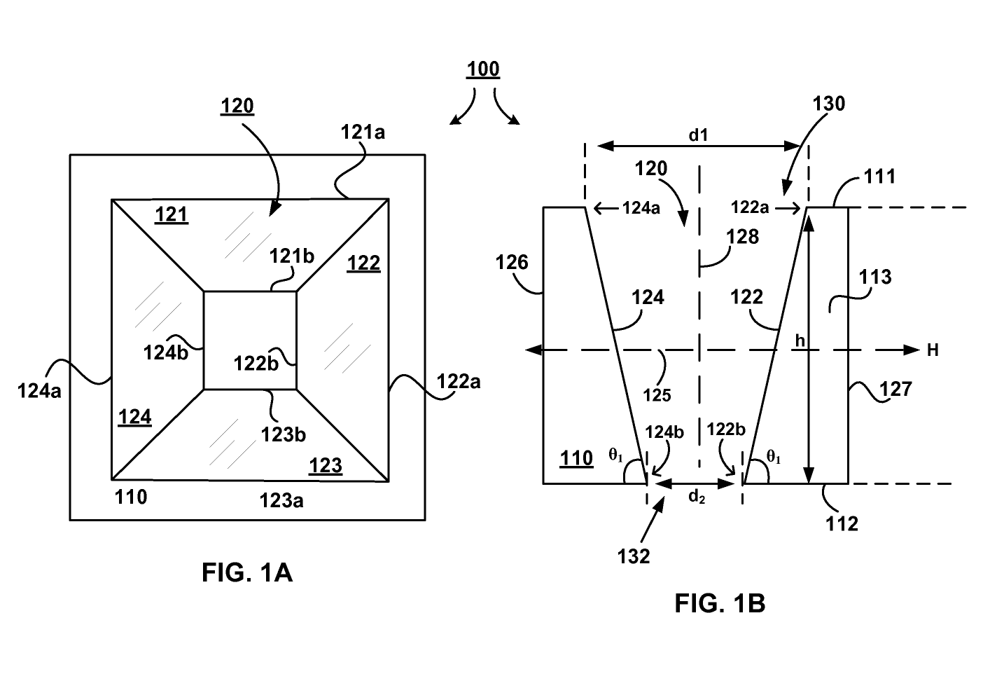

The description will be made as to the embodiments of the present invention in conjunction with the accompanying drawings of FIGS. 1-5. In accordance with the purposes of this invention, as embodied and broadly described herein, this invention, in one aspect, relates to a bottomless micro-mirror well. Wells can be etched through the full thickness of a silicon wafer, to form a mirrored well with sides but an open bottom, or they can be molded or cast out of plastic and then coated with a reflective metallic coating to form mirrors.

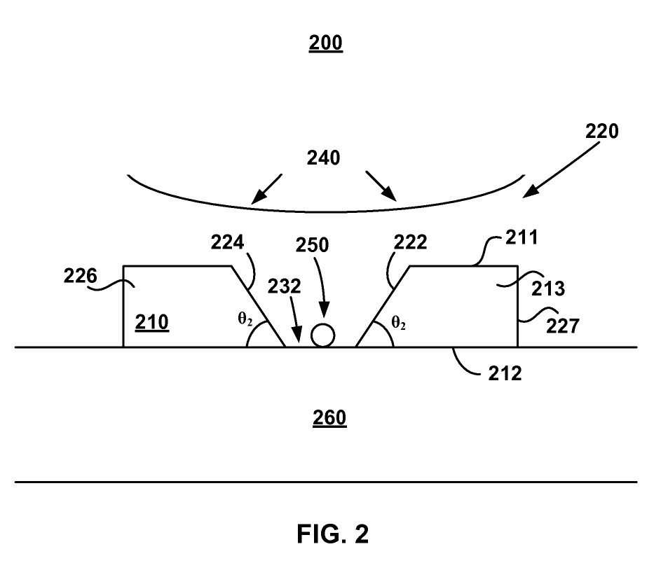

In one embodiment, now referring to FIGS. 1A and 1B, the bottomless micro-mirror well 100 includes a substrate 110 having a first surface 111 and an opposite, second surface 112 defining a body portion 113 between the first surface 111 and the second surface 112. The body portion 113 has a thickness, H. The body portion 113 defines a bottomless inverted pyramidal well 120 having at least three side surfaces 121, 122, 123 and 124 extending to each other and defining a first opening 130 and a second opening 132, between a first sidewall 126 and a second sidewall 127. Each of the side surfaces 121-124 has a first end (121a, 122a, 123a, or 124a) and a second end (121b, 122b, 123b, or 124b) such that the first opening 130 is formed by the respective first ends 121a, 122a, 123a, 124a of the side surfaces 121-124 and the second opening 132 is formed by the respective second ends 121b, 122b, 123b, 124b of the side surfaces 121-124. Each of the at least three side surfaces 121-124 is configured to reflect light emitting from an object of interest (see e.g. FIGS. 2, 250), and each has an angle, θ₁ relative to the second surface 112, in the range of 0<θ₁<90°. That is, each of the at least three side surfaces 121-124 defines an angle θ₁ relative to a horizontal axis 125 that is orthogonal to a vertical axis 128 such that 0<θ₁<90°. As shown, the diameter d₁ of the first opening 130 is greater than the diameter d₂ of the second opening 132. The angles defined between the side surfaces 121-124 and the second surface 112 can be the same, or different. Each of the at least three side surfaces 121-124 may comprise a dichroic mirror, and the substrate 110 may include a silicon wafer. The horizontal cross-sectional shape of the inverted pyramidal well 120 shown in FIG. 1 is a square, but alternatively the cross-sectional shape can be another type of polygon, a circle, or an elongated circle. A microfluidic structure may be provided that is in communication with the bottomless mirrored pyramidal well on either or both sides.

Now referring to FIG. 2, a partial, cross-sectional view of an inverted three-dimensional microscope 200 is shown, with a bottomless inverted pyramidal well 220 having introverted wells for collecting images of an object of interest 250, according to one embodiment of the present invention. The bottomless inverted pyramidal well 220 includes a substrate 210 having a first surface 211 and an opposite, second surface 212 defining a body portion 213 between the first surface 211 and the second surface 212. The body portion 213 defines the bottomless inverted pyramidal well 220 having side surfaces 221 (not shown), 222, 223 (not shown), and 224 that extend to each other and define an opening 232 between a first sidewall 226 and a second sidewall 227 of the body portion 213. Each of the side surfaces 221-224 is configured to reflect light emitting from the object of interest 250 and each defines an angle θ₂ relative to the second surface 212, in the range of 45°<θ₂<90°. As shown, the objective 240 is disposed above the transparent glass or plastic coverslip 260 holding the object of interest 250 and the object of interest 250 is disposed in the opening 232 defined by the bottomless inverted pyramidal well 220. The inverted pyramidal well 220 has a focus (not shown) being equidistant from all of the at least three side surfaces 221-224, and the position of the focus is inside the inverted pyramidal well 220. In operation, the inverted pyramidal well 220 is positioned in relation to the object of interest 250 such that the object of interest 250 is located inside of the inverted pyramidal well 220.

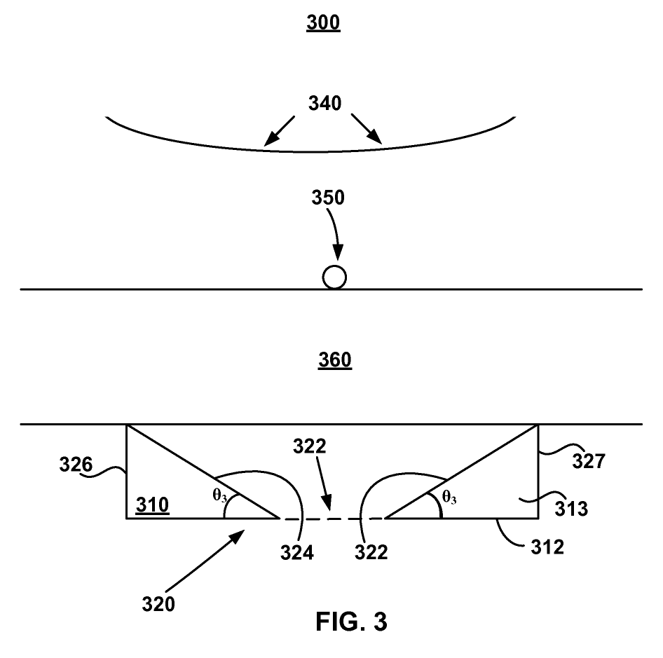

Now referring to FIG. 3, a partial, cross-sectional view of an upright three-dimensional microscope 300 is shown, with a bottomless inverted pyramidal well 320 having extroverted wells for collecting images of an object of interest 350, according to one embodiment of the present invention. The bottomless inverted pyramidal well 320 includes a substrate 310 and a body portion 313. The body portion 313 defines the bottomless inverted pyramidal well 320, which has side surfaces 321 (not shown), 322, 323 (not shown), and 324 that extend to each other and define an opening 332 between a first sidewall 326 and a second sidewall 327 of the body portion 313. Each of the side surfaces 321-324 is configured to reflect light emitted from the object of interest 350 and each defines an angle θ₃ relative to a surface 312, where 0<θ₃<45°. As shown, the objective 340 is disposed above the transparent glass or plastic coverslip 360 holding the object of interest 350 and the bottomless inverted pyramidal well 320 is disposed beneath the coverslip 360 and the object of interest 350. The inverted pyramidal well 320 has a focus (not shown) and the position of the focus is outside the inverted pyramid well 320. In operation, the inverted pyramidal well 320 is positioned in relation to the object of interest 350 such that the object of interest 350 is located outside of the inverted pyramidal well 320.

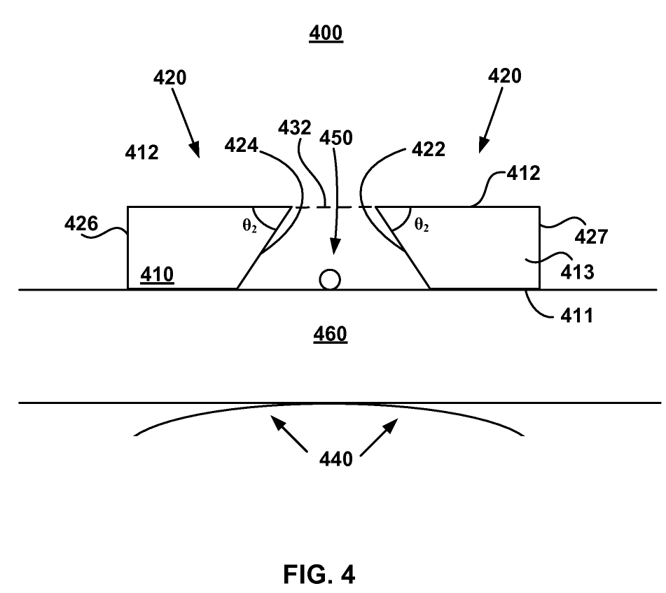

Now referring to FIG. 4, a partial, cross-sectional view of an inverted three-dimensional microscope 400 is shown, with a bottomless pyramidal well 420 having introverted wells for collecting images of an object of interest 450 within the well, according to one embodiment of the present invention. The bottomless pyramidal well 420 includes a substrate 410 having a first surface 411 and an opposite, second surface 412 defining a body portion 413 between the first surface 411 and the second surface 412. The body portion 413 defines side surfaces 421 (not shown), 422, 423 (not shown), and 424, which extend to each other and define an opening 432 between a first sidewall 426 and a second sidewall 427 of the body portion 413. Each of the side surfaces 421-424 is configured to reflect light emitted from the object of interest 450 and each defines an angle θ₂ relative to the second surface 412, in the range of 45<θ₂<90°. As shown, the objective 440 is disposed beneath the coverslip 460 holding the object of interest 450 and the bottomless pyramidal well 420 is disposed on the coverslip 460 such that the object of interest 450 is located inside the bottomless pyramidal well 420.

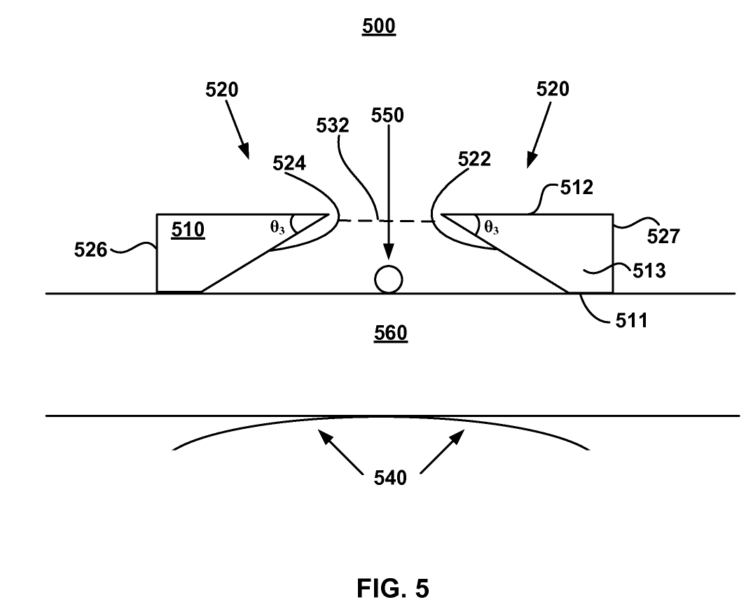

Now referring to FIG. 5, a partial, cross-sectional view of an inverted three-dimensional microscope 500 is shown, with a bottomless pyramidal well 520 having extroverted wells for collecting images of an object of interest 550, according to one embodiment of the present invention. The bottomless pyramidal well 520 includes a substrate 510 having a first surface 511 and an opposite, second surface 512 defining a body portion 513 between the first surface 511 and the second surface 512. The bottomless pyramidal well 520 has side surfaces 521 (not shown), 522, 523 (not shown), and 524, which extend to each other and define an opening 532 between a first sidewall 526 and a second sidewall 527 of the body portion 513. Each of the side surfaces 521-524 is configured to reflect light from the object of interest 550 and each defines an angle θ₃ relative to the second surface 512, in a range of 0°<θ₃<45°. As shown, the objective 540 is disposed beneath the coverslip 560, which holds the object of interest 550.

In another aspect, the present invention relates to a process of fabricating a bottomless micro-mirror well. In one embodiment, the process includes the steps of providing a silicon substrate and etching off the silicon substrate to form a bottomless inverted pyramidal well in the silicon substrate, where the bottomless inverted pyramidal well has a first end, an opposite, second end, and a plurality of side surfaces extending to each other and defining an opening at the second end. The process also includes the step of performing photolithographically masking and evaporating processes on the plurality of side surfaces so as to form the bottomless mirrored pyramidal well.

The etching step is performed with a potassium hydroxide (KOH) etching process. The bottomless inverted pyramidal well further includes a central axis running through the center of the well from a first end to a second end and a planar axis perpendicular to the central axis, and wherein each of the plurality of side surfaces is formed to define an angle θ₁ relative to the planar axis.

In another aspect, the present invention relates to a three-dimensional microscope. In one embodiment, the three-dimensional microscope includes an objective lens that focuses the light from a plurality of mirrors configured to simultaneously collect images of an object of interest from multiple vantage points, where the plurality of mirrors forms at least one bottomless mirrored pyramidal well, and where each of the plurality of mirrors has an angle θ₁ relative to a horizontal axis that is orthogonal to a vertical axis, in the range of 0<θ₁<90°. The bottomless pyramidal well is made from the smooth angled surfaces of anisotropically etched silicon. In one embodiment, a microfluidic structure is in communication with the at least one bottomless mirrored pyramidal well, and the object of interest includes a biological analyte including cells and proteins. Each of the plurality of mirrors has a dichroic mirror capable of reflecting specific wavelength ranges into a collection cone of the microscope objective lens. In one embodiment, the plurality of mirrors is affixed such that the perimeter of the field of view of the microscope objective lens contains reflected images of an object of interest.

In another embodiment, the plurality of mirrors is affixed opposite an object of interest from the microscope objective lens for collecting reflected images of the object of interest.

In yet another aspect, the present invention relates to a method for reconstruction of simultaneous, multi-vantage point images into three-dimensional structures of an object of interest. In one embodiment, the method includes the steps of simultaneously collecting images of the object of interest from multiple vantage points surrounding the object of interest and mapping the collected images of the object of interest to form a three-dimensional image displaying the three-dimensional structures of the object of interest. The step of simultaneously collecting images of the object of interest is performed with a bottomless mirrored pyramidal well having a plurality of side mirrored surfaces extending to each other and defining a first opening and a second opening, where each of the plurality of side mirrored surfaces has a first end and a second end such that the first opening is formed by the respective plurality of first ends of the side mirrored surfaces and the second opening is formed by the respective second ends of the side mirrored surfaces, such that each of the plurality of side mirrored surfaces has an angle, θ₁ relative to a horizontal axis that is orthogonal to a vertical axis, in the range of 0<θ₁<90°, and where the diameter of the first opening is greater than the diameter of the second opening. The step of simultaneously collecting images of the object of interest includes the step of collecting light from simultaneously emitting fluorophores of the object of interest.

According to one or more embodiments of the present invention as set forth above, bottomless, mirrored pyramidal wells are provided which can be physically attached to the objective of an upright microscope and lowered down over a small specimen that is attached to a slide. Bottomless wells can also be incorporated into a microfluidic device where the flow is through the open bottom, allowing the possibility of three-dimensional tracking or even dynamic trapping, as cells or particles move through the system.

Also, according to one or more embodiments of the present invention as set forth above, an in-vivo image of a cell (wide-field and confocal, bright-field and fluorescent) can be acquired by means of an introverted well that is polished to remove material from the back surface of the substrate into which the well is formed such that the bottom of the well no longer exists. The bottomless introverted well provides a declinated perspective of in-vivo tissue when placed (without compression) directly on the tissue in question. In addition to the ordinary (XY) microscope or confocal plane, the bottomless mirrored pyramidal well provides four planes which are nearly orthogonal to the XY plane, and thus gives access to planes which may contain the entire junction between adjacent and connected cells, for instance, the junction between epithelial cells.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A bottomless micro-mirror well, comprising a substrate having a first surface and an opposite, second surface defining a body portion therebetween, wherein the body portion defines an inverted pyramidal well having at least three side surfaces extending to each other and defining an opening between a first sidewall and a second sidewall, wherein each of the at least three side surfaces is configured to reflect light emitting from an object of interest.

2. The bottomless micro-mirror well of claim 1, wherein each of the at least three side surfaces defines an angle θ₁, relative to the second surface, and wherein 0°<θ₁<90°.

3. The bottomless micro-mirror well of claim 1, wherein the inverted pyramidal well has a focus being equidistant from all of the at least three side surfaces, and wherein the position of the focus is inside the inverted pyramidal well.

4. The bottomless micro-mirror well of claim 1, wherein the inverted pyramidal well has a focus and the position of the focus is outside the inverted pyramidal well.

5. The bottomless micro-mirror well of claim 1, wherein the cross-sectional shape of the inverted pyramidal well is a polygon, a circle, or an elongated circle.

6. The bottomless micro-mirror well of claim 1, wherein the object of interest comprises a biological analyte including cells and proteins.

7. The bottomless micro-mirror well of claim 1, wherein the substrate comprises a silicon wafer.

8. The bottomless micro-mirror well of claim 1, wherein in operation, the inverted pyramidal well is positioned in relation to the object of interest such that the object of interest is located inside of the inverted pyramidal well.

9. The bottomless micro-mirror well of claim 1, wherein in operation, the inverted pyramidal well is positioned in relation to the object of interest such that the object of interest is located outside of the inverted pyramidal well.

10. The bottomless micro-mirror well of claim 1, wherein each of the at least three side surfaces comprises a dichroic mirror.

11. A process of fabricating a bottomless micro-mirror well, comprising the steps of:
(a) providing a silicon substrate;
(b) etching off the silicon substrate to form a bottomless inverted pyramidal well therein, wherein the bottomless inverted pyramidal well has a first end, an opposite, second end, and a plurality of side surfaces extending to each other and defining an opening at the second end; and
(c) performing photolithographically masking and evaporating processes on the plurality of side surfaces so as to form a mirrored pyramid well.

12. The process of claim 11, wherein the etching step is performed with a potassium hydroxide (KOH) etching process.

13. The process of claim 11, wherein the bottomless inverted pyramidal well further comprises a central axis running through the center thereof and a planar axis perpendicular to the central axis, and wherein each of the plurality of side surfaces is formed to define an angle θ₁ relative to the planar axis.

14. The process of claim 11, further comprising the step of fabricating a master mold from the mirrored pyramidal well for replication of at least one additional mirrored pyramidal well.

15. The process of claim 14, wherein the master mold is fabricated through at least one of hot embossing, injection molding, and casting.

16. A three-dimensional microscope, comprising a microscope objective lens adapted for focusing light from a plurality of mirrors configured to simultaneously collect images of an object of interest from multiple vantage points, wherein the plurality of mirrors forms at least one bottomless mirrored pyramidal well, wherein each of the plurality of mirrors has an angle θ₁ relative to a horizontal axis that is orthogonal to a vertical axis, and wherein the angle θ₁ is in the range of 0<θ₁<90°.

17. The three-dimensional microscope of claim 16, further comprising a microfluidic structure in communication with the at least one bottomless mirrored pyramidal well.

18. The three-dimensional microscope of claim 16, wherein the at least one bottomless pyramidal well is made from the smooth angled surfaces of anisotropically etched silicon.

19. The three-dimensional microscope of claim 16, wherein the object of interest comprises a biological analyte including cells and proteins.

20. The three-dimensional microscope of claim 16, wherein each of the plurality of mirrors comprises a dichroic mirror capable of reflecting specific wavelength ranges into a collection cone of the microscope objective lens.

21. The three-dimensional microscope of claim 16, wherein the plurality of mirrors is affixed such that the perimeter of the field of view of the microscope objective lens contains reflected images of the object of interest.

22. The three-dimensional microscope of claim 16, wherein the plurality of mirrors is affixed opposite the object of interest from the microscope objective lens for collecting reflected images of the object of interest.

23. A method for reconstruction of simultaneous, multi-vantage point images into three-dimensional structures of an object of interest, comprising the steps of:
(a) simultaneously collecting images of the object of interest from multiple vantage points surrounding the object of interest; and
(b) mapping the collected images of the object of interest to form a three-dimensional image displaying the three-dimensional structures of the object of interest,
wherein the step of simultaneously collecting images of the object of interest is performed with a bottomless mirrored pyramidal well having a plurality of side mirrored surfaces extending to each other and defining a first opening and a second opening, wherein each of the plurality of side mirrored surfaces has a first end and a second end such that the first opening is formed by the respective first ends of the side mirrored surfaces and the second opening is formed by the respective second ends of the side mirrored surfaces, and such that each of the plurality of side mirrored surfaces has an angle θ₁ relative to a horizontal axis that is orthogonal to a vertical axis, wherein the angle θ₁ is in a range of 0<θ₁<90°, and wherein the diameter of the first opening is greater than the diameter of the second opening.

24. The method of claim 23, wherein the step of simultaneously collecting images of the object of interest comprises the step of collecting light from simultaneously emitting fluorophores of the object of interest.
